(19) United States
(12) Patent Application Publication
(10) Pub. No.: US 2026/0295456 A1
(43) Pub. Date: Oct. 1, 2026

(54) LIQUID MATERIAL VAPORIZING DEVICE

(71) Applicant: HORIBA STEC, Co., Ltd., Kyoto-shi (JP)

(72) Inventors: Keisuke NISHIWAKI, Kyoto-shi (JP); Ichiro NISHIKAWA, Kyoto-shi (JP); Kenichi AMIMOTO, Kyoto-shi (JP); Soichiro HIRAI, Kyoto-shi (JP)

(21) Appl. No.: 19/573,310

(22) Filed: Mar. 20, 2026

(30) Foreign Application Priority Data
Mar. 27, 2025 (JP) 2025-053462

(51) Int. Cl. B01D 1/00

(52) U.S. Cl. CPC B01D 1/0011; B01D 1/0064; B01D 1/0082

(57) ABSTRACT

The present invention vaporizes a liquid material while preventing metal elution, and includes a main body block having a mixing portion that mixes a liquid material and a carrier gas, a liquid material supply pipe that supplies the liquid material to the main body block, a gas-liquid mixture lead-out pipe that leads out the gas-liquid mixture from the main body block, and a heating unit that heats the gas-liquid mixture lead-out pipe, in which the main body block is formed of ceramics or plastic, the liquid material supply pipe is formed of ceramics or plastic, and the gas-liquid mixture lead-out pipe is formed of ceramics.

### CROSS-REFERENCE TO RELATED APPLICATIONS

The present application claims priority to Japanese Patent Application No. 2025-053462 filed Mar. 27, 2025, which is incorporated herein by reference in its entirety.

### BACKGROUND OF THE INVENTION

### Technical Field

The present invention relates to a liquid material vaporizing device.

### Description of the Related Art

Conventionally, for example, as a device for generating a material gas in a semiconductor manufacturing process such as a film forming process, there is a device for vaporizing a liquid material to generate a material gas as disclosed in JP 2017-104815 A. The liquid material vaporizing device includes a main body block that mixes a liquid material and a carrier gas, a liquid material supply pipe that supplies the liquid material to the main body block, a gas-liquid mixture lead-out pipe that leads out the gas-liquid mixture from the main body block, and a heating unit that heats the gas-liquid mixture. The main body block, the liquid material supply pipe, and the gas-liquid mixture lead-out pipe are formed using stainless steel having high heat resistance and corrosion resistance.

However, metal elution from a main body block or the like formed of stainless steel becomes a problem along with high accuracy and high quality of a semiconductor manufacturing process in recent years, a change in a liquid material to be used, or the like. Elution of metal into the liquid material may adversely affect the quality and the like in the subsequent semiconductor manufacturing process.

### Prior Art Document

### Patent Document

JP 2017-104815 A

### SUMMARY OF THE INVENTION

Therefore, the present invention has been made to solve the above-described problems, and an object thereof is to vaporize a liquid material while preventing metal elution.

That is, the liquid material vaporizing device according to the present invention includes a main body block that mixes a liquid material and a carrier gas, a liquid material supply pipe that supplies the liquid material to the main body block, a gas-liquid mixture lead-out pipe that leads out the gas-liquid mixture from the main body block, and a heating unit that heats the gas-liquid mixture lead-out pipe, in which the main body block is formed of ceramics or plastic, the liquid material supply pipe is formed of ceramics or plastic, and the gas-liquid mixture lead-out pipe is formed of ceramics.

In such a liquid material vaporizing device, since the main body block is formed of ceramics or plastic, the liquid material supply pipe is formed of ceramics or plastic, and the gas-liquid mixture lead-out pipe is formed of ceramics, elution of metal into the liquid material and the gas-liquid mixture can be prevented. In addition, since the gas-liquid mixture lead-out pipe heated by the heating unit is formed of ceramics having a higher thermal conductivity than plastic, the liquid material can be efficiently heated in the gas-liquid mixture lead-out pipe to generate vaporized gas.

The main body block, the liquid material supply pipe, and the gas-liquid mixture lead-out pipe may be configured by separate members from one another.

With this configuration, each member can be easily manufactured.

In a case where the liquid material supply pipe and the gas-liquid mixture are connected to the main body block, it is conceivable to connect them by fastening bolts. Specifically, it is conceivable that the liquid material supply pipe and the gas-liquid mixture lead-out pipe have a flange portion that is formed with an insertion hole through which a fastening bolt to be fastened to the main body block is inserted and is formed of ceramics. In the case of sealing between the main body block and the flange portion, it is conceivable to form an accommodation groove for accommodating a seal member in the flange portion.

However, in a case where the accommodation groove is formed in the flange portion, the mechanical strength of the portion where the accommodation groove is formed decreases, and the flange portion is easily damaged by tightening the fastening bolt.

Therefore, the main body block may be formed with an accommodation groove for accommodating the seal member on a surface facing the flange portion.

In order to disperse the stress applied to the flange portion by tightening the fastening bolt to make the flange portion less likely to be damaged, a reinforcing plate may be provided between a head portion of the fastening bolt and the flange portion.

It is conceivable that the flange portion is formed with a plurality of the insertion holes in a circumferential direction, and the reinforcing plate is common to a plurality of the fastening bolts to be inserted into the plurality of insertion holes.

With this configuration, it is possible to disperse stress due to fastening each of the fastening bolts in a wide range.

The liquid material vaporizing device of the present invention further includes a control valve that is provided in the main body block and adjusts a flow rate of the liquid material. Since a valve body of the control valve is also in contact with the liquid material, when the valve body is formed of metal, metal is eluted from the valve body. In order to prevent elution of metal from the valve body, the valve body of the control valve may be subjected to resin coating.

As a specific embodiment of the heating unit, it is conceivable to have a heat transfer block provided so as to surround an outer peripheral surface of the gas-liquid mixture lead-out pipe and a heater built in the heat transfer block. In this case, a load is applied to the gas-liquid mixture lead-out pipe by the heat transfer block and a cartridge heater, and the gas-liquid mixture lead-out pipe may be damaged.

In order to prevent the gas-liquid mixture lead-out pipe from being damaged by the load of the heating unit, the heat transfer block or the heater may be supported by a support member provided separately from the gas-liquid mixture lead-out pipe.

In order to facilitate attachment of the heat transfer block to the gas-liquid mixture lead-out pipe and prevent an excessive impact on the gas-liquid mixture lead-out pipe, the heat transfer block may include a plurality of block bodies formed of aluminum, and may be attached to the gas-liquid mixture lead-out pipe by fastening the plurality of block bodies with a fastening member.

The liquid material vaporizing device of the present invention further includes a carrier gas supply pipe that is connected to the main body block and supplies the carrier gas to the main body block. The carrier gas supply pipe may be formed of ceramics or plastic.

With this configuration, the liquid material supply pipe and the carrier gas supply pipe can be a common component. In addition, even when the liquid material flows back into the carrier gas supply pipe, elution of the metal can be prevented.

The ceramics is desirably silicon carbide (SiC). Silicon carbide (SiC) is free from metal elution particularly among other ceramics such as alumina, and thus is suitable for the purpose of the present invention. In addition, SiC is excellent in thermal conductivity, and when the gas-liquid mixture lead-out pipe is formed of SiC, the liquid material can be efficiently heated.

The plastic is made of desirably a fluorine-based resin or a polyether ether ketone resin (PEEK resin). Here, examples of the fluorine-based resin include polytetrafluoroethylene (PTFE), perfluoroalkoxy alkane (PFA), and ethylene-tetrafluoroethylene (ETFE).

The liquid material vaporizing device according to the present invention includes: a main body block to which a liquid material is supplied; a control valve that is provided in the main body block and adjusts a flow rate of the liquid material; a liquid material supply pipe that supplies the liquid material to the main body block; a liquid material lead-out pipe that leads out the liquid material from the main body block; and a heating unit that heats the liquid material lead-out pipe, in which the main body block is formed of ceramics or plastic, the liquid material supply pipe is formed of ceramics or plastic, and the liquid material lead-out pipe is formed of ceramics.

As described above, according to the present invention, it is possible to vaporize the liquid material while preventing metal elution.

### BRIEF DESCRIPTION OF THE DRAWINGS

FIG. 1 is a cross-sectional view schematically illustrating a configuration of a liquid material vaporizing device according to an embodiment of the present invention;

FIG. 2 is a plan view illustrating a main body block, a liquid material supply pipe, a carrier gas supply pipe, and a gas-liquid mixture lead-out pipe of the embodiment;

FIG. 3A is a cross-sectional view of a heating unit of the embodiment, and FIG. 3B is an exploded cross-sectional view of the heating unit;

FIG. 4 is an enlarged cross-sectional view of a valve body of a control valve of the embodiment;

FIG. 5 is a cross-sectional view illustrating a connection structure of the main body block and the flange portion of the embodiment;

FIG. 6A is a perspective view in which a reinforcing plate of the embodiment is incorporated, and FIG. 6B is a perspective view of the reinforcing plate;

FIG. 7 is a schematic view illustrating a state in which a heating unit is supported with respect to a casing in the embodiment;

FIG. 8 is a schematic view illustrating a configuration of a liquid material vaporizing device of a modification;

FIG. 9A is a rear view, FIG. 9B is a side view, and FIG. 9C is a perspective view illustrating a configuration of a flange portion of the modification;

FIG. 10A is a perspective view of a liquid material supply pipe and FIG. 10B is a perspective view of a carrier gas supply pipe, illustrating a configuration of the flange portion of the modification; and

FIG. 11 is a cross-sectional view schematically illustrating a configuration of a liquid material vaporizing device of another modification according to the embodiment of the present invention.

### DETAILED DESCRIPTION

Hereinafter, an embodiment of a liquid material vaporizing device according to the present invention will be described with reference to the drawings. Note that any of the drawings below is schematically illustrated by being omitted or exaggerated as appropriate for easy understanding. The same components are denoted by the same reference numerals, and the description thereof will be omitted as appropriate.

### Basic Configuration of Liquid Material Vaporizing Device 100

The liquid material vaporizing device 100 according to the present embodiment is for supplying a predetermined flow rate of material gas to a chamber or the like incorporated in a semiconductor manufacturing line or the like and used in a semiconductor manufacturing process, for example.

Specifically, the liquid material vaporizing device 100 mixes a liquid material LM and a carrier gas CG to generate a gas-liquid mixture GL, and heats the gas-liquid mixture GL to vaporize the liquid material LM contained in the gas-liquid mixture GL to generate a material gas MG.

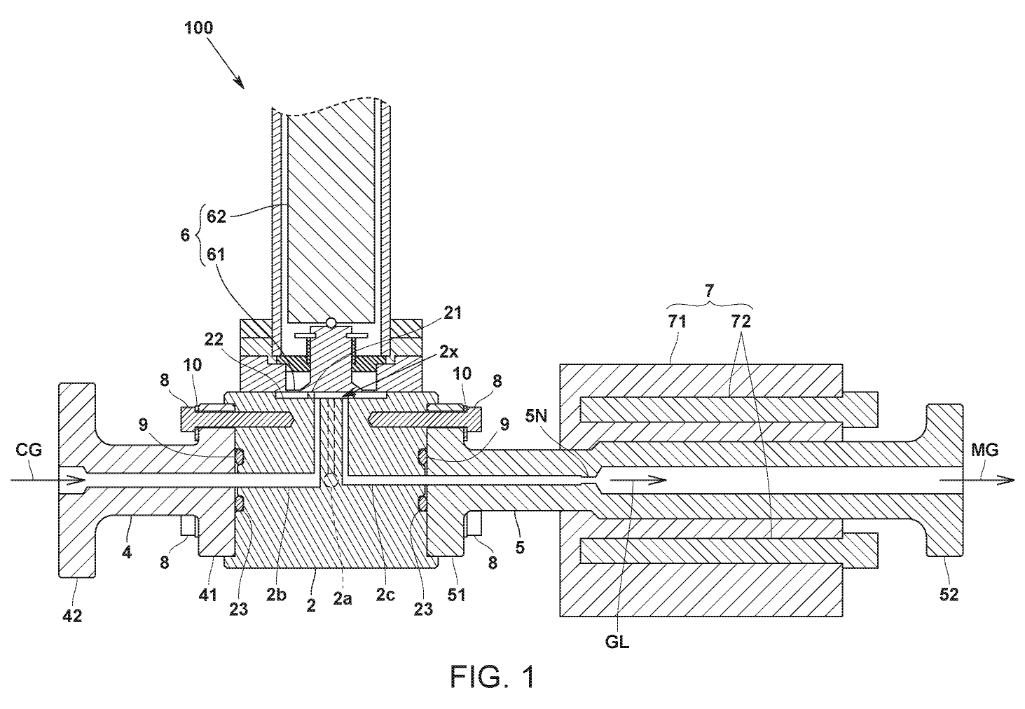

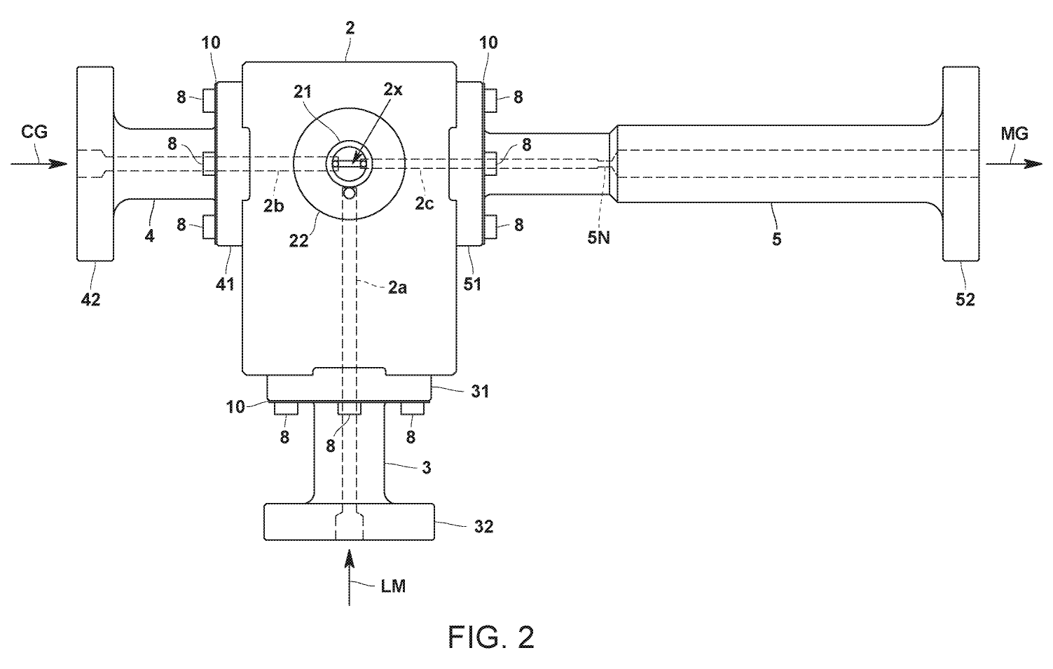

As illustrated in FIGS. 1 and 2, the liquid material vaporizing device includes a main body block 2 that mixes a liquid material LM and a carrier gas CG, a liquid material supply pipe 3 that supplies the liquid material LM to the main body block 2, a carrier gas supply pipe 4 that supplies the carrier gas CG to the main body block 2, a gas-liquid mixture lead-out pipe 5 that leads out the gas-liquid mixture GL from the main body block 2, a control valve 6 that is provided in the main body block 2 and adjusts a flow rate of the liquid material LM, and a heating unit 7 that heats the gas-liquid mixture GL by heating the gas-liquid mixture lead-out pipe 5. In FIG. 2, illustration of the control valve 6 and the heating unit 7 is omitted.

The main body block 2 has a mixing portion 2x that mixes the liquid material LM and the carrier gas CG. In addition, the main body block 2 is formed with a liquid material flow path 2a through which the liquid material LM flows, a carrier gas flow path 2b through which the carrier gas CG flows, and a gas-liquid mixture flow path 2c through which the gas-liquid mixture GL flows.

Then, a merging portion of the liquid material flow path 2a and the carrier gas flow path 2b becomes a mixing portion 2x of the liquid material LM and the carrier gas CG. A gas-liquid mixture flow path 2c is connected to the mixing portion 2x. The mixing portion 2x opens to the inside of a valve seat 21 formed on the upper surface of the main body block 2. The control valve 6 abuts on or separates from the valve seat 21. An annular groove 22 in which the liquid material flow path 2a is opened is formed around the valve seat 21 on the upper surface of the main body block 2.

The liquid material supply pipe 3 is connected to an upstream side of the liquid material flow path 2a of the main body block 2, and the liquid material LM is supplied to the liquid material flow path 2a. A carrier gas supply pipe 4 is connected to the upstream side of a carrier gas flow path 2b of the main body block 2, and the carrier gas CG is supplied to the carrier gas flow path 2b. A gas-liquid mixture lead-out pipe 5 is connected to a downstream side of the gas-liquid mixture flow path 2c of the main body block 2, and a gas-liquid mixture is led out from the gas-liquid mixture flow path 2c. A connection structure of these pipes 3 to 5 will be described later.

The control valve 6 functions as a flow rate control valve, and is provided on the upper surface of the main body block 2 via a seal member (not illustrated) as illustrated in FIG. 1. The control valve 6 includes a diaphragm 61 that is a valve body abutting on or separating from the valve seat 21 of the main body block 2, and an actuator 62 that presses and deforms the diaphragm 61. Note that the actuator 62 uses, for example, a piezo stack.

When the diaphragm 61 of the control valve 6 is separated from the valve seat 21, the liquid material LM flows into the mixing portion 2x from the liquid material flow path 2a through the annular groove 22, and the liquid material LM and the carrier gas CG are mixed to generate the gas-liquid mixture GL.

Here, a mass flowmeter (not illustrated) that measures the flow rate of the liquid material LM flowing through the liquid material supply pipe 3 is provided on the upstream side of the liquid material supply pipe 3. The control valve 6 is subjected to feedback control based on a measurement value of a mass flowmeter so that the liquid material LM supplied to the mixing portion 2x has a predetermined flow rate. A mass flow controller that adjusts the flow rate of the carrier gas flowing through the carrier gas supply pipe 4 is provided on the upstream side of the carrier gas supply pipe 4.

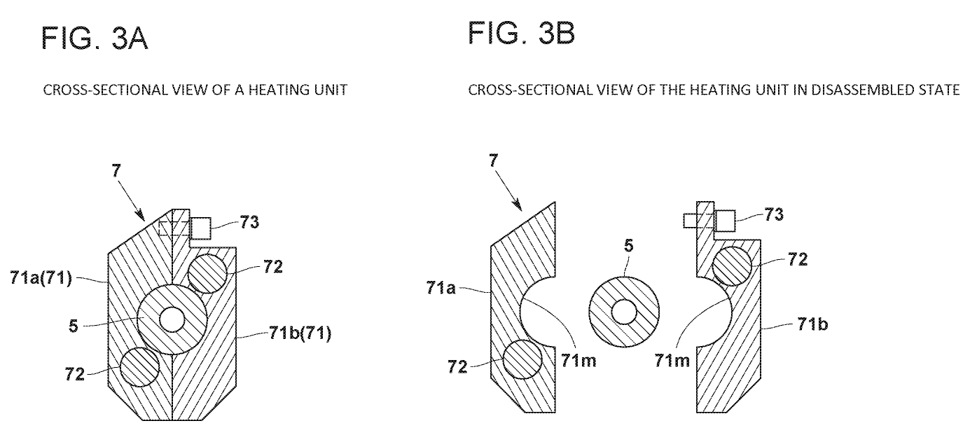

As illustrated in FIGS. 1 and 3, the heating unit 7 has a heat transfer block 71 provided so as to surround an outer peripheral surface of the gas-liquid mixture lead-out pipe 5, and a heater 72 built in the heat transfer block 71.

As illustrated in FIG. 3, the heat transfer block 71 transfers heat of the heater 72 to the gas-liquid mixture lead-out pipe 5, and has a plurality of (here, two) block bodies 71a and 71b formed of aluminum. On the inner surface of each of the block bodies 71a and 71b, a recessed groove 71m having, for example, a semi-cylindrical shape is formed in contact with the outer peripheral surface of the gas-liquid mixture lead-out pipe 5. These two block bodies 71a and 71b are fastened by the fastening member 73 in a state of being attached to the gas-liquid mixture lead-out pipe 5, and are attached to the gas-liquid mixture lead-out pipe 5. Note that the heat transfer block 71 may be divided into three or more.

The heater 72 is a cartridge heater incorporated in the heat transfer block 71. The heater 72 is incorporated in the heat transfer block 71 by being inserted into a mounting hole formed in the heat transfer block 71. When an aluminum nitride heater or the like is used as the heater 72, the thermal expansion coefficient is close to that of SiC, and thus the aluminum nitride heater may be directly attached to the gas-liquid mixture lead-out pipe 5.

The gas-liquid mixture GL flowing through the gas-liquid mixture lead-out pipe 5 is heated by the heating unit 7 configured as described above. The present embodiment has a configuration in which a nozzle portion 5N (see FIG. 1) is formed inside the gas-liquid mixture lead-out pipe 5, and the gas-liquid mixture GL is sprayed with the nozzle portion 5N, so as to promote the vaporization of the liquid material LM.

### Configuration for Preventing Metal Elution

The liquid material vaporizing device 100 of the present embodiment has a configuration in which metal is not eluted into the liquid material LM and the gas-liquid mixture GL.

Specifically, the main body block 2, the liquid material supply pipe 3, and the gas-liquid mixture lead-out pipe 5 are formed of ceramics excellent in heat resistance and corrosion resistance. In the present embodiment, the carrier gas supply pipe 4 is also formed of ceramics. Silicon carbide (SiC) is used as the ceramics. Silicon carbide (SiC) is free from metal elution particularly among other ceramics such as alumina. The main body block 2, the liquid material supply pipe 3, the gas-liquid mixture lead-out pipe 5, and the carrier gas supply pipe 4 are configured by separate members from one another.

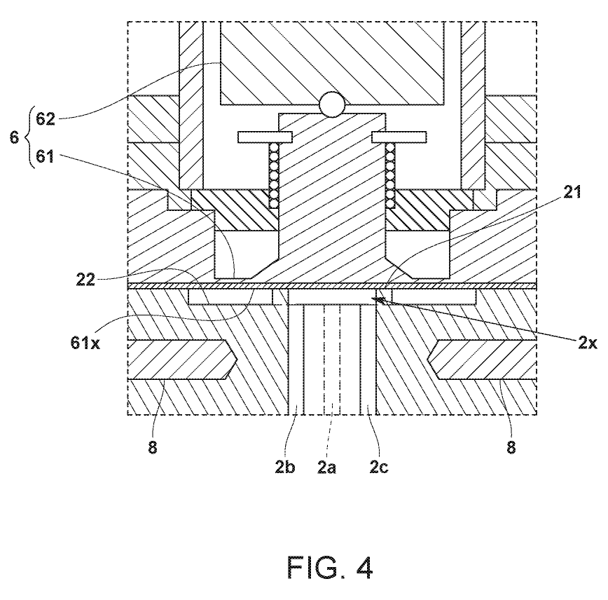

Resin coating is applied to the diaphragm 61 which is a valve body of the control valve 6 is subjected to resin coating. Specifically, as illustrated in FIG. 4, the entire seating surface which is a liquid contact surface of the diaphragm 61 is subjected to resin coating, to form a resin layer 61x.

As the resin coating, a fluorine-based resin coating is applied. Examples of the fluorine-based resin to be coated include polytetrafluoroethylene (PTFE), perfluoroalkoxy alkane (PFA), and ethylene-tetrafluoroethylene (ETFE).

With such a configuration, in the liquid material vaporizing device 100, the flow path through which the liquid material LM passes and the flow path through which the gas-liquid mixture GL passes are formed of ceramics and a fluorine-based resin and have no metal. In addition, since the gas-liquid mixture lead-out pipe 5 heated by the heating unit 7 is formed of ceramics having a higher thermal conductivity than plastic, thermal conductivity from the heating unit 7 to the gas-liquid mixture GL can be improved, and thus the liquid material LM can be efficiently heated in the gas-liquid mixture lead-out pipe 5 to generate vaporized gas.

### Connection Structure between Main Body Block 2 and Pipes 3 to 5

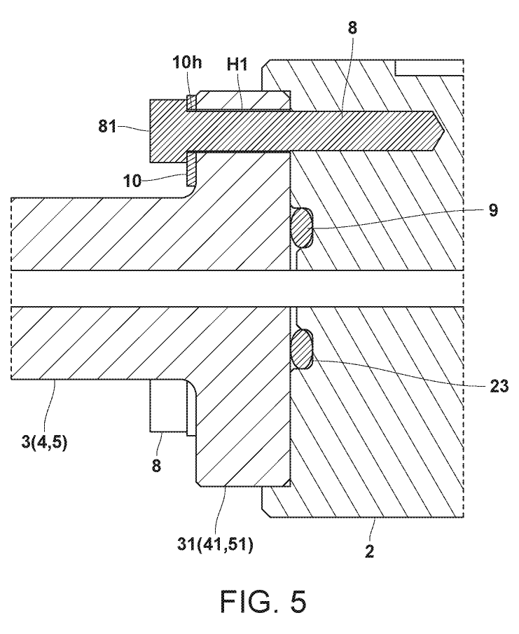

As illustrated in FIGS. 1, 2, and 5, the liquid material supply pipe 3, the carrier gas supply pipe 4, and the gas-liquid mixture lead-out pipe 5 have flange portions 31, 41, and 51 for connecting to the main body block 2. As illustrated in FIG. 5, these flange portions 31, 41, and 51 are formed with insertion holes H1 through which the fastening bolts 8 to be fastened to the main body block 2 are inserted. Each of the flange portions 31, 41, and 51 of the present embodiment is formed with a plurality of (here, three) insertion holes H1 in the circumferential direction. The flange portions 31, 41, and 51 are fastened and fixed to the main body block 2 by the three fastening bolts 8. Consequently, the liquid material supply pipe 3, the carrier gas supply pipe 4, and the gas-liquid mixture lead-out pipe 5 are connected to the main body block 2.

Therefore, the main body block 2 is formed with an accommodation groove 23 for accommodating the seal member 9 on a surface facing the flange portions 31, 41, and 51 of the respective pipes 3 to 5. Here, as the seal member 9, for example, an O-ring formed of fluorine rubber can be used.

Specifically, on a side surface of the main body block 2 that is formed with the upstream side opening of the liquid material flow path 2a, an accommodation groove 23 is formed in a portion facing the flange portion 31 of the liquid material supply pipe 3 so as to surround the upstream side opening of the liquid material flow path 2a. In addition, on the side surface of the main body block 2 that is formed with the upstream side opening of the carrier gas flow path 2b, an accommodation groove 23 is formed in a portion facing the flange portion 41 of the carrier gas supply pipe 4 so as to surround the upstream side opening of the carrier gas flow path 2b. In addition, on the side surface of the main body block 2 that is formed with the upstream side opening of the gas-liquid mixture flow path 2c, an accommodation groove 23 is formed in a portion facing the flange portion 51 of the gas-liquid mixture lead-out pipe 5 so as to surround the upstream side opening of the gas-liquid mixture flow path 2c.

Therefore, when the main body block 2 is formed with the accommodation groove 23 that accommodates the seal member 9, the flange portions 31, 41, and 51 of the respective pipes 3 to 5 are not required to be formed with the accommodation groove 23. Specifically, surfaces of the flange portions 31, 41, and 51 facing the main body block 2 can be flat surfaces. In addition, the thicknesses of the flange portions 31, 41, and 51 can be increased. As a result, the mechanical strength of the flange portions 31, 41, and 51 even formed of ceramics or plastic can be improved. In addition, rising portions (root portions) of the flange portions 31, 41, and 51 are formed with rounded portions where stresses are concentrated, thereby improving mechanical strength.

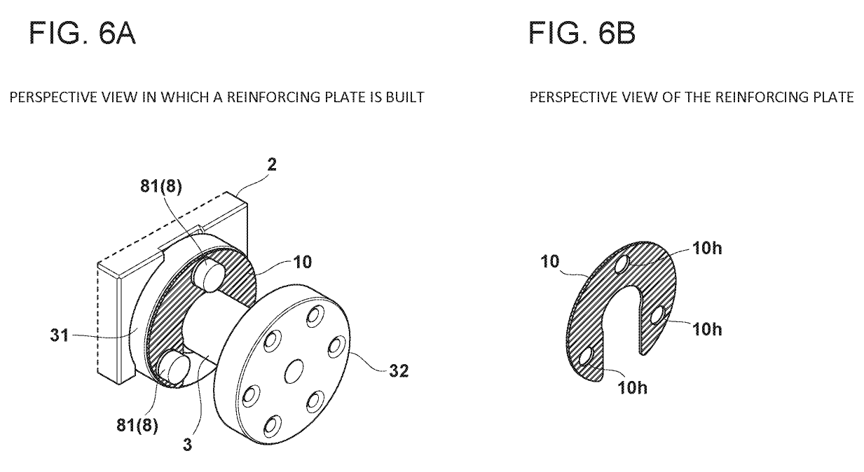

In addition, the liquid material vaporizing device 100 of the present embodiment, particularly as illustrated in FIGS. 5 and 6, is provided with the reinforcing plate 10 between head portions 81 of the fastening bolt 8 and the flange portions 31, 41, and 51.

The reinforcing plate 10 disperses stress applied to the flange portions 31, 41, and 51 from the head portions 81 of the fastening bolt 8 when the fastening bolt 8 is fastened. The reinforcing plate 10 is a member separate from a washer externally fitted to the fastening bolt 8, and has a larger contact area with the flange portions 31, 41, and 51 than the washer.

The reinforcing plate 10 of the present embodiment is common to the plurality of fastening bolts 8 inserted into the plurality of insertion holes H1. Specifically, the reinforcing plate 10 has a shape along the circumferential direction of the flange portions 31, 41, and 51, and is formed with a plurality of through holes 10h corresponding to the plurality of insertion holes H1. The reinforcing plate 10 is a member common to the three fastening bolts 8, but may be provided for each fastening bolt 8, or may be a member common to the two or more fastening bolts 8.

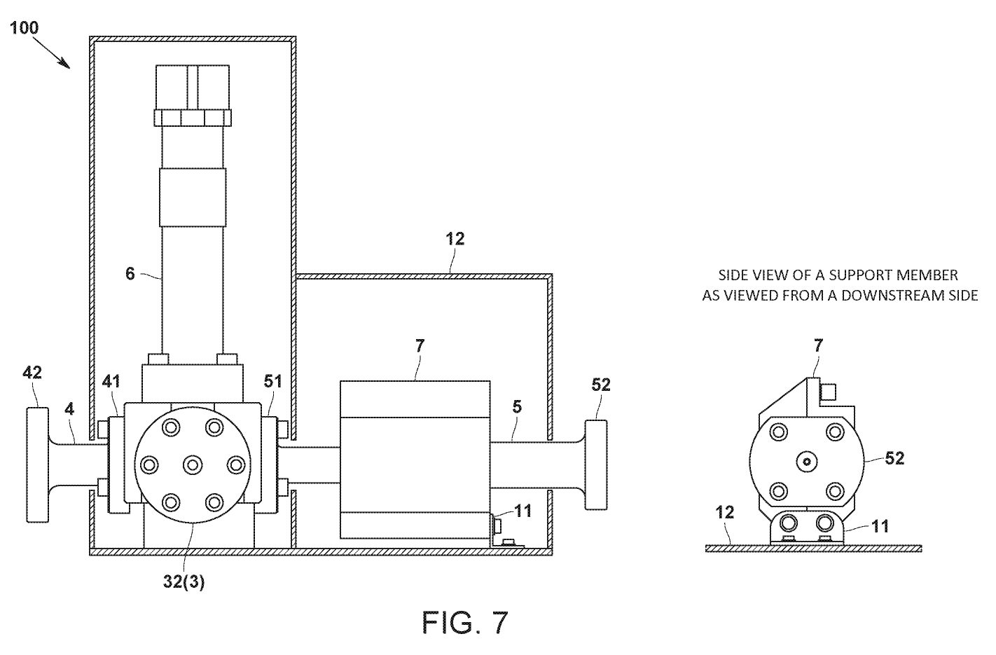

Furthermore, since the heating unit 7 is provided in the gas-liquid mixture lead-out pipe 5 formed of ceramics, stress may be applied to the flange portion 51 of the gas-liquid mixture lead-out pipe 5 by the load of the heating unit 7 to cause damage. In addition, the flange portion 51 may be damaged by an impact applied to the gas-liquid mixture lead-out pipe 5 during mounting the device, during transportation, or the like. Therefore, as illustrated in FIG. 7, the heat transfer block 71 or the heater 72 is supported by the support member 11, in order to support the heating unit 7 and reduce the load on the gas-liquid mixture lead-out pipe 5.

The support member 11 is provided separately from the gas-liquid mixture lead-out pipe 5. Specifically, the support member 11 is coupled to the casing 12 that accommodates at least the main body block 2 and the heating unit 7, and is coupled to the heat transfer block 71. The support member 11 of the present embodiment is substantially L-shaped, and one flat plate portion 11a is connected to a bottom surface portion of the casing 12, and the other flat plate portion 11b is connected to a side surface portion of the heat transfer block 71. In addition, the flange portion 52 on the downstream side of the gas-liquid mixture lead-out pipe 5 is a deformed flange so as not to interfere with the fastening of the fixing screw that fixes the heat transfer block 71 to the support member 11.

A flange portion 32 on the upstream side of the liquid material supply pipe 3 extends from the side surface of the casing 12, and an external pipe formed of, for example, a fluorine-based resin that supplies the liquid material LM is connected thereto. A flange portion 42 on the upstream side of the carrier gas supply pipe 4 extends from the side surface of the casing 12, and an external pipe formed of, for example, a fluorine-based resin that supplies the carrier gas CG is connected thereto. Furthermore, a flange portion 52 on the downstream side of the gas-liquid mixture lead-out pipe 5 extends from the side surface of the casing 12, and an external pipe formed of, for example, a fluorine-based resin that leads out the vaporized material gas MG is connected thereto.

### Effects of Present Embodiment

As described above, according to the liquid material vaporizing device 100 of the present embodiment, since the main body block 2 is formed of ceramics, the liquid material supply pipe 3 is formed of ceramics, and the gas-liquid mixture lead-out pipe 5 is formed of ceramics, elution of metal into the liquid material LM and the gas-liquid mixture GL can be prevented.

### Other Embodiments

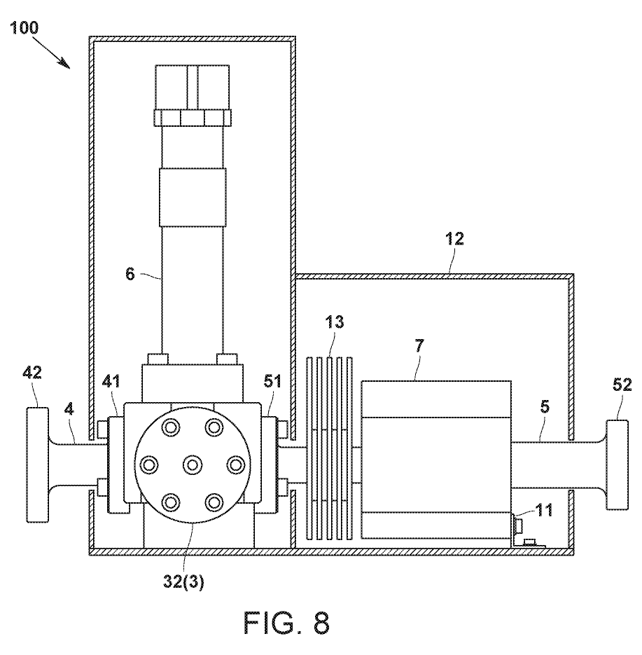

For example, as illustrated in FIG. 8, in the gas-liquid mixture lead-out pipe 5, a heat dissipation fin 13 may be provided between the flange portion 51 and the heating unit 7. The heat dissipation fin 13 is formed of, for example, aluminum, and is provided so as to surround the outer peripheral surface of the gas-liquid mixture lead-out pipe 5. Similarly to the heat transfer block 71, it is conceivable that the heat dissipation fin 13 also has two block bodies, and the two block bodies are fastened by a fastening member in a state of being attached to the gas-liquid mixture lead-out pipe 5, and are attached to the gas-liquid mixture lead-out pipe 5. Therefore, when the heat dissipation fin 13 is provided, heat transfer to the main body block 2 and the control valve 6 via the gas-liquid mixture lead-out pipe 5 can be reduced, and the thermal influence on the control valve 6 and the like can be reduced. In addition, a heat dissipation fin may be provided in the main body block 2 to reduce heat transfer to the control valve 6 and reduce thermal influence on the control valve 6 and the like.

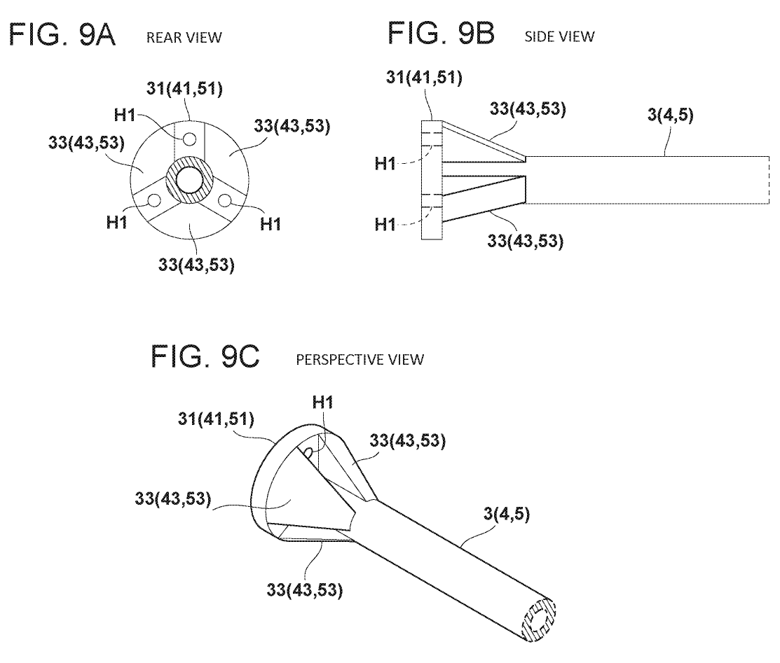

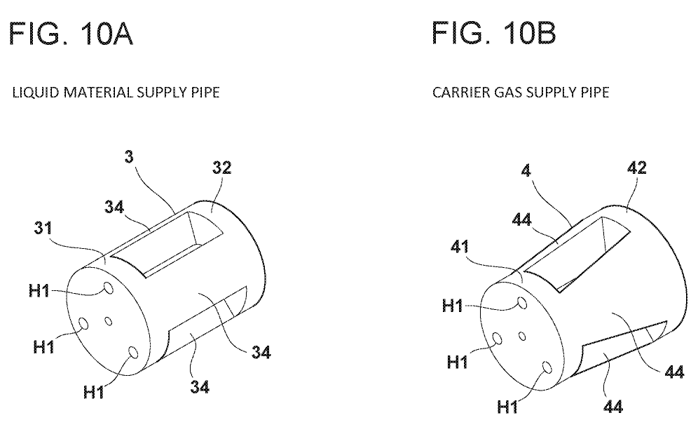

As a configuration for improving the mechanical strength of the flange portions 31, 41, and 51, as illustrated in FIG. 9, one or a plurality of rib portions 33, 43, and 53 connecting the back surfaces of the flange portions 31, 41, and 51 to the outer peripheral surfaces of the respective pipes 3, 4, and 5 may be formed. Therefore, when the rib portions 33, 43, and 53 are formed, the mechanical strength of the respective flange portions 31, 41, and 51 can be improved. Furthermore, in the liquid material supply pipe 3 in which the heating unit 7 is not provided, as illustrated in FIG. 10A, the rib portion 34 may be formed along the outer peripheral surface over the flange portion 31 on the downstream side and the flange portion 32 on the upstream side of the liquid material supply pipe 3. Similarly, in the carrier gas supply pipe 4 in which the heating unit 7 is not provided, as illustrated in FIG. 10B, the rib portion 44 may be formed along the outer peripheral surface over the flange portion 41 on the downstream side and the flange portion 42 on the upstream side of the carrier gas supply pipe 4. Therefore, when the rib portions 34 and 44 are formed, the mechanical strength of the respective flange portions 31, 41, and 51 can be improved.

At least one of the main body block 2, the liquid material supply pipe 3, and the carrier gas supply pipe 4 may be formed of solid nonmetal, synthetic resin, or plastic having excellent heat resistance and corrosion resistance. The plastic is desirably a fluorine-based resin or a polyether ether ketone resin (PEEK resin). Here, examples of the fluorine-based resin include polytetrafluoroethylene (PTFE), perfluoroalkoxy alkane (PFA), and ethylene-tetrafluoroethylene (ETFE).

Furthermore, the main body block 2 may be integrally formed with at least one of the liquid material supply pipe 3, the carrier gas supply pipe 4, and the gas-liquid mixture lead-out pipe 5. In the case of integrally forming including the gas-liquid mixture lead-out pipe 5, it is conceivable of integrally forming using ceramics. In the case of integrally forming without including the gas-liquid mixture lead-out pipe 5, it is conceivable of integrally forming using ceramics or plastic.

In addition, the main body block 2 may be provided with a heater to heat the liquid material LM flowing through the liquid material flow path 2a or the gas-liquid mixture GL flowing through the gas-liquid mixture flow path 2c.

In a case where the temperature for vaporizing the liquid material LM is low, the valve body 61 of the control valve 6 can be formed of plastic.

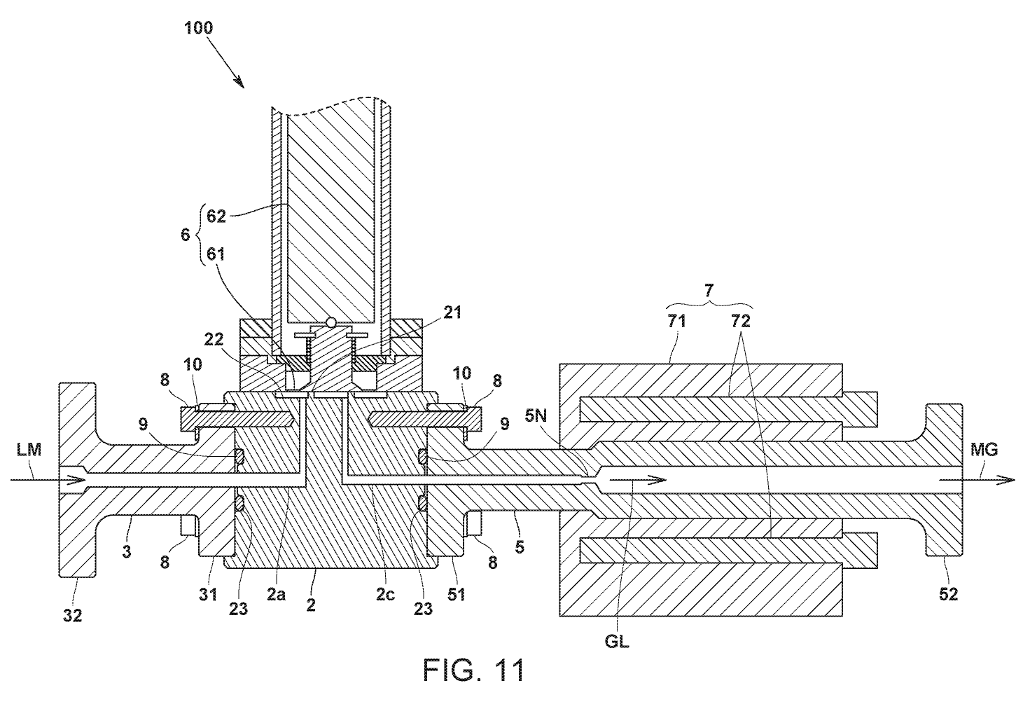

In addition, in the above embodiment, the liquid material is vaporized after the gas-liquid mixture is generated by mixing the liquid material and the carrier gas, but the carrier gas may not be used. In this case, as illustrated in FIG. 11, the main body block 2 of the liquid material vaporizing device 100 has no carrier gas flow path 2b. Specifically, the liquid material vaporizing device 100 includes a main body block 2 to which the liquid material LM is supplied, a control valve 6 that is provided in the main body block 2 and adjusts a flow rate of the liquid material LM, a liquid material supply pipe 3 that supplies the liquid material LM to the main body block 2, a liquid material lead-out pipe 5 that leads the liquid material LM from the main body block 2, and a heating unit 7 that heats the liquid material lead-out pipe 5. The liquid material lead-out pipe 5 has the same configuration as the gas-liquid mixture lead-out pipe 5 of the above embodiment. The configurations of the other portions and units are also similar to those of the above embodiment.

A gas-liquid mixing device may be configured using the structure of the liquid material vaporizing device 100 of the above embodiment. The gas-liquid mixing device has no vaporizing unit of the above embodiment. That is, the gas-liquid mixing device includes the main body block 2 that mixes the liquid material LM and the carrier gas CG, the liquid material supply pipe 3 that supplies the liquid material LM to the main body block 2, the carrier gas supply pipe 4 that supplies the carrier gas CG to the main body block 2, and the gas-liquid mixture lead-out pipe 5 that leads out the gas-liquid mixture GL from the main body block 2. The main body block 2 is formed of ceramics or plastic. The liquid material supply pipe 3 is formed of ceramics or plastic. The carrier gas supply pipe 4 is formed of ceramics or plastic. The gas-liquid mixture lead-out pipe 5 is formed of ceramics or plastic.

In addition, various modifications and combinations of the embodiments may be made without departing from the gist of the present invention.

### REFERENCE CHARACTER LIST

100 Liquid material vaporizing device

LM Liquid material

CG Carrier gas

GL Gas-liquid mixture

2 Main body block

3 Liquid material supply pipe

31 Flange portion

4 Carrier gas supply pipe

41 Flange portion

5 Gas-liquid mixture lead-out pipe

51 Flange portion

6 Control valve

61 Valve body

7 Heating unit

71 Heat transfer block

71a, 71b Block body

72 Heater

8 Fastening bolt

H1 Insertion hole

9 Seal member

23 Accommodation groove

10 Reinforcing plate

11 Support member

What is claimed is:

1. A liquid material vaporizing device, comprising:
a main body block that mixes a liquid material and a carrier gas,
a liquid material supply pipe that supplies the liquid material to the main body block,
a gas-liquid mixture lead-out pipe that leads out the gas-liquid mixture from the main body block, and
a heating unit that heats the gas-liquid mixture lead-out pipe, wherein
the main body block is formed of ceramics or plastic,
the liquid material supply pipe is formed of ceramics or plastic, and
the gas-liquid mixture lead-out pipe is formed of ceramics.

2. The liquid material vaporizing device according to claim 1, wherein the main body block, the liquid material supply pipe, and the gas-liquid mixture lead-out pipe are configured by separate members from one another.

3. The liquid material vaporizing device according to claim 1, wherein
the liquid material supply pipe and the gas-liquid mixture lead-out pipe have a flange portion that is formed with an insertion hole through which a fastening bolt to be fastened to the main body block is inserted, and
the main body block is formed with an accommodation groove for accommodating a seal member on a surface facing the flange portion.

4. The liquid material vaporizing device according to claim 1, wherein
the liquid material supply pipe and the gas-liquid mixture lead-out pipe have a flange portion that is formed with an insertion hole through which a fastening bolt to be fastened to the main body block is inserted, and
a reinforcing plate is provided between a head portion of the fastening bolt and the flange portion.

5. The liquid material vaporizing device according to claim 4, wherein
the flange portion is formed with a plurality of the insertion holes in a circumferential direction, and the reinforcing plate is common to a plurality of the fastening bolts to be inserted into the plurality of insertion holes.

6. The liquid material vaporizing device according to claim 1, further comprising a control valve that is provided to the main body block and adjusts a flow rate of the liquid material, wherein
a valve body of the control valve is subjected to resin coating.

7. The liquid material vaporizing device according to claim 1, wherein
the heating unit has
a heat transfer block provided so as to surround an outer peripheral surface of the gas-liquid mixture lead-out pipe, and
a heater built in the heat transfer block, and
the heat transfer block or the heater is supported by a support member provided separately from the gas-liquid mixture lead-out pipe.

8. The liquid material vaporizing device according to claim 7, wherein
the heat transfer block includes a plurality of block bodies formed of aluminum, and is attached to the gas-liquid mixture lead-out pipe by fastening the plurality of block bodies with a fastening member.

9. The liquid material vaporizing device according to claim 1, further comprising a carrier gas supply pipe that supplies the carrier gas to the main body block, wherein
the carrier gas supply pipe is formed of ceramics or plastic.

10. The liquid material vaporizing device according to claim 1, wherein the ceramics is SiC.

11. The liquid material vaporizing device according to claim 1, wherein the plastic is a fluorine-based resin or a polyether ether ketone resin (PEEK resin).

12. A liquid material vaporizing device, comprising:
a main body block to which a liquid material is supplied;
a control valve that is provided in the main body block and adjusts a flow rate of the liquid material;
a liquid material supply pipe that supplies the liquid material to the main body block;
a liquid material lead-out pipe that leads out the liquid material from the main body block; and
a heating unit that heats the liquid material lead-out pipe, wherein
the main body block is formed of ceramics or plastic,
the liquid material supply pipe is formed of ceramics or plastic, and
the liquid material lead-out pipe is formed of ceramics.
